(19) United States
(12) Patent Application Publication
(10) Pub. No.: US 2019/0058001 A1
(43) Pub. Date: Feb. 21, 2019

(54) X RAY FLAT PANEL DETECTOR AND FABRICATION METHOD THEREOF

(71) Applicant: BOE TECHNOLOGY GROUP CO., LTD., BEIJING (CN)

(72) Inventor: Hui TIAN, Beijing (CN)

(21) Appl. No.: 15/767,584

(22) PCT Filed: Sep. 28, 2017
(86) PCT No.: PCT/CN2017/103971

§ 371 Date: Apr. 11, 2018

(30) Foreign Application Priority Data
Feb. 23, 2017 (CN) 201710099045.2

(51) Int. Cl. H01L 27/146; H01L 31/0224; H01L 31/0216; H01L 31/0352; H01L 31/0296; H01L 31/18

(52) U.S. Cl. CPC H01L 27/14663; H01L 27/14612; H01L 31/022408; H01L 27/14636; H01L 31/02161; H01L 31/035218; H01L 31/1828; H01L 27/14689; H01L 27/14685; H01L 27/14696; H01L 27/14698; H01L 31/1868; H01L 27/14692; H01L 31/0296

(57) ABSTRACT

The present disclosure relates to an X ray flat panel detector and a fabrication method thereof. The X ray flat panel detector comprises: a substrate; a thin film transistor disposed on the substrate and configured to output a sensed signal; an insulating layer covering the thin film transistor; a photosensitive device disposed on the insulating layer to have a vertical shift with respect to the thin film transistor, and configured to absorb visible light through a quantum dot film and convert the visible light into a sensed signal; and a scintillating layer disposed on the photosensitive device and configured to convert X rays into the visible light.

### CROSS-REFERENCE TO RELATED APPLICATIONS

This application is a U.S. National Stage under 35 U.S.C. § 371 of PCT/CN2017/103971, filed on Sep. 28, 2017, which claims priority to and the benefit of Chinese Patent Application No. 201710099045.2, filed on Feb. 23, 2017, the entire contents of which are hereby incorporated by reference as part of this application.

### TECHNICAL FIELD

The present disclosure relates to the technical field of detection and, in particular, to an X ray flat panel detector and a fabrication method thereof.

### BACKGROUND

At present, digitized photography has been widely used in medical instruments, for example, in an X ray machine for taking X ray chest radiography. A critical component of an X ray machine is the flat panel detector (FPD) for acquiring images, which functions to convert X rays into digital image signals. Owing to advantages of amorphous silicon flat panel detectors, such as good capability of photoelectric conversion, stability of performance and the like, amorphous silicon flat panel detectors are drastically improved in recent years.

An amorphous silicon (a-Si) flat panel detector is a detector with indirect conversion, whose main structure includes thin film transistors (TFTs), photodiodes and a scintillating layer. The scintillating layer is used to convert X rays into visible light, the photodiodes are used to convert the visible light into charge carriers and store them, and the thin film transistors function as a switch. Under the control of an external scan controlling circuit, the thin film transistors are turned on row by row, allowing the charge carriers stored in the photodiodes to be read and transferred to a data processing circuit.

### SUMMARY

In accordance with some embodiments of the present disclosure, there is provided an X ray flat panel detector including: a substrate; a thin film transistor disposed on the substrate and configured to output a sensed signal; an insulating layer covering the thin film transistor; a photosensitive device disposed on the insulating layer to have a vertical shift with respect to the thin film transistor, and configured to absorb visible light through a quantum dot film and convert the visible light into a sensed signal; and a scintillating layer disposed on the photosensitive device and configured to convert X rays into the visible light.

Optionally, the photosensitive device may include: a sensing electrode disposed on the insulating layer, connected with a drain electrode of the thin film transistor and configured to sense charge carriers and generate a sensed signal; a composite insulating layer covering the sensing electrode; and a quantum dot film disposed on the composite insulating layer, and configured to absorb the visible light and convert the visible light into the charge carriers.

Optionally, the photosensitive device may further include a driving electrode and a metal lead wire.

Optionally, the driving electrode and the metal lead wire may be located in a same layer as the sensing electrode.

Optionally, the quantum dot film may include at least one of a cadmium telluride film or a cadmium telluride/cadmium sulfide film and have a thickness of 100-300 nm.

Optionally, the scintillating layer may include a scintillating layer composed of cesium iodide and have a thickness of 400-600 um, the cesium iodide in the scintillating layer forming a crystalline array arranged in a columnar shape.

Optionally, the composite insulating layer may include a composite organic-inorganic insulating layer and have a thickness of 100-300 nm.

Optionally, the X ray flat panel detector may further include a passivation layer disposed between the photosensitive device and the scintillating layer.

Optionally, the passivation layer may include at least one of a silicon nitride layer or a silicon oxide layer.

Some embodiments of the present disclosure further provide an X ray imaging system including the above-mentioned X ray flat panel detector.

Some embodiments of the present disclosure further provide a fabrication method of an X ray flat panel detector, the fabrication method including: fabricating a thin film transistor and an insulating layer on a substrate; fabricating a photosensitive device on the insulating layer; and fabricating a scintillating layer on the photosensitive device.

Optionally, fabricating a photosensitive device on the insulating layer may include: fabricating a sensing electrode and a driving electrode on the insulating layer by a patterning process, the sensing electrode being connected with a drain electrode of the thin film transistor; and fabricating the composite insulating layer and the quantum dot film.

Optionally, the composite insulating layer includes a composite organic-inorganic insulating layers and has a thickness of 100-300 nm; the quantum dot film includes at least one of a cadmium telluride film or a cadmium telluride/cadmium sulfide film and has a thickness of 100-300 nm; the scintillating layer includes a scintillating layer composed of cesium iodide and has a thickness of 400-600 um, the cesium iodide in the scintillating layer forming a crystalline array arranged in a columnar shape.

Optionally, the fabrication method may further include: fabricating a passivation layer on the photosensitive devices; and fabricating the scintillating layer on the passivation layer.

Optionally, the passivation layer may include at least one of a silicon nitride layer or a silicon oxide layer.

What given above is only illustrative description of products and methods in accordance with the present disclosure. Various features and corresponding advantages of the present disclosure will be explained with the following embodiments of the specification, and will be apparent in part from the embodiments or understood by carrying out the present invention. Various purposes and advantages of embodiments of the present invention may be realized and achieved by the structures indicated particularly in the specification, claims and accompanying drawings.

### BRIEF DESCRIPTION OF THE DRAWINGS

Accompanying drawings are used to facilitate further understanding of the present disclosure, and are incorporated as a part of the present specification in order to explain, but not limit, the technical solutions of the present disclosure in connection with embodiments of the present application. Shapes and sizes of components in the drawings do not reflect the real scale, but only serve to illustrate the contents of the present disclosure schematically.

FIG. 1 is a schematic structural diagram of an amorphous silicon flat panel detector in the related art;

FIG. 2 is a schematic structural diagram of an X ray flat panel detector in an embodiment of the present disclosure;

FIG. 3 is a schematic diagram illustrating the structure of pixels of an X ray flat panel detector in an embodiment of the present disclosure;

FIG. 4 is an absorption spectrogram of a quantum dot film; and

FIG. 5 is a flow chart of a fabrication method of an X ray flat panel detector in an embodiment of the present disclosure.

### DETAILED DESCRIPTION

Specific implementations of the present disclosure will be further described in detail below with reference to accompanying drawings and embodiments. The following embodiments are used for explaining the present disclosure rather than limiting the scope thereof. It is to be noted that embodiments and features thereof in the present application may be used in any combination as long as no collision occurs.

FIG. 1 is a schematic structural diagram of an amorphous silicon flat panel detector in the related art. As shown in FIG. 1, the main structure of the flat panel detector includes a substrate 10, a thin film transistor 11 disposed on the substrate 10, a photodiode 12 located substantially in the same horizontal plane as the thin film transistor 11, an insulating layer 13 covering the thin film transistor 11 and the photodiode 12, and a scintillating layer 14 formed on the insulating layer 13. Generally, the thin film transistor 11 includes a gate, a gate insulating layer, an active layer, and a source electrode and a drain electrode; and the photodiode includes a P-type region, an N-type region and an intrinsic region located therebetween with the N-type region connected with a drain electrode of the thin film transistor. Although in FIG. 1, only a thin film transistor 11 and a photodiode 12 are shown, those skilled in the art can understand that the flat panel detector may comprise one or more thin film transistors 11 and one or more photodiodes 12. The flat panel detector operates in the principle that X rays are modulated by the human body in their paths, the modulated X rays R are converted into visible light L by the scintillating layer 14, the visible light L is absorbed by the photodiode 12 and converted into charge carriers, the charge carriers are stored in a storage capacitor or the photodiode's own capacitor as image charges, and thin film transistors 11 are turned on in a row by row sequence by an external scan controlling circuit to output the image charges to an external data processing circuit in an manner that the image charges from the same row are read at the same time. The quantity of image charges read through each thin film transistor 11 corresponds to the dose of the incident X rays. Through processing by the external data processing circuit, it is able to determine the quantity of charges and in turn the dose of X rays at each pixel.

In the amorphous silicon flat panel detector shown in FIG. 1, since the photodiode and the thin film transistor are disposed side by side and the photodiode is arranged in a pixel region, the signal to noise ratio and the resolution of the flat panel detector are inter-conditioned. If the photosensitive area of the photodiode is small, the signal to noise ratio will be low, such that the detection efficiency decreases; if the photosensitive area of the photodiode is increased, the area of the pixel region will be increased, such that the resolution decreases.

With the continual development of application of digital X ray imaging systems in the specialized fields of medical, industrial or the like, it is difficult for the amorphous silicon flat panel detectors of conventional structures to satisfy future demands and it has become one of the most urgent needs to achieve flat panel detecting technologies with relatively high a quantum efficiency and a resolution.

Embodiments of the present disclosure provide an X ray flat panel detector and a fabrication method thereof to overcome at least in part the disadvantage of the inter-conditioned signal to noise ratio and resolution of the X ray flat panel detectors in the related art and to improve the detection efficiency and resolution.

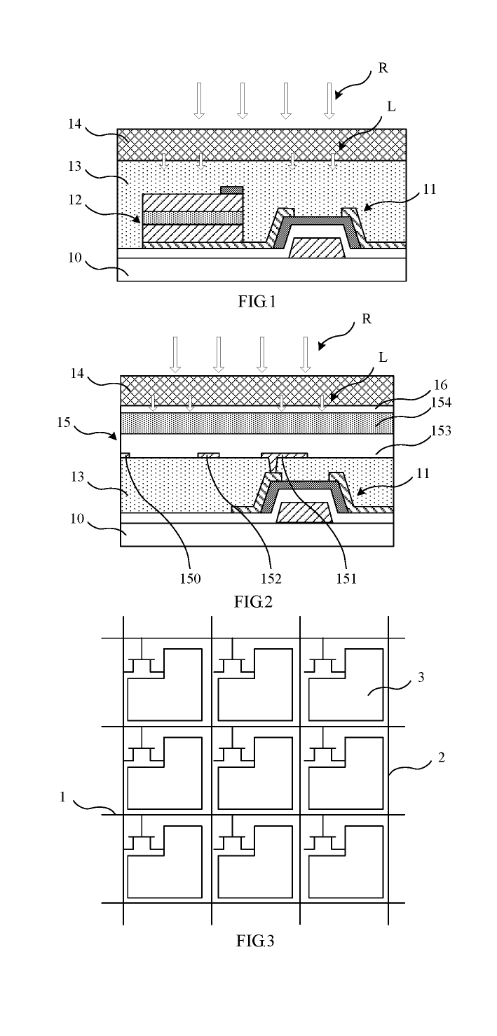

An embodiment of the present disclosure provides an X ray flat panel detector. FIG. 2 is a schematic structural diagram of an X ray flat panel detector in an embodiment of the present disclosure. As shown in FIG. 2, the main structure of the X ray flat panel detector includes a substrate 10 as well as a thin film transistor 11, an insulating layer 13, a photosensitive device 15 and a scintillating layer 14 formed in this order on the substrate 10. For example, the thin film transistor 11 is disposed on the substrate 10, the insulating layer 13 covers the thin film transistor 11, the photosensitive device 15 is disposed on the insulating layer 13 to have a vertical shift with respect to the thin film transistor 11 and uses a quantum dot film as its photosensitive layer to absorb visible light, a passivation layer 16 is disposed on the photosensitive device 15 and the scintillating layer 14 is disposed on the passivation layer 16. Although in FIG. 2, only a thin film transistor 11 and a photosensitive device 15 are shown, those skilled in the art can understand that the X ray flat panel detector may comprise one or more thin film transistors 11 and one or more photosensitive devices 15.

In some embodiments of the present disclosure, the thin film transistor includes a gate, a gate insulating layer, an active layer, a source electrode and a drain electrode; the photosensitive device 15 includes a sensing electrode 151, a driving electrode 152, a composite insulating layer 153 and a quantum dot film 154; the sensing electrode 151 and the driving electrode 152 are disposed on the insulating layer 13 covering the thin film transistor 11, the sensing electrode 151 is connected to the drain electrode of the thin film transistor 11 through an insulating layer via opened in the insulating layer 13, the composite insulating layer 153 covers the sensing electrode 151 and the driving electrode 152, and the quantum dot film 154 is disposed on the composite insulating layer 153.

The operation procedure of the flat panel detector in the embodiment of the present disclosure is that the scintillating layer 14 converts X rays R into visible light L, the quantum dot film 154 of the photosensitive device 15 that functions as the photosensitive layer absorbs the visible light L and converts the visible light L into charge carriers, the sensing electrode 151 in the photosensitive device 15 senses the charge carriers from the quantum dot film 154 and generates a sensed signal, and the sensed signal is read and output to an external data processing circuit when the thin film transistor is turned on, wherein the driving electrode 152 is used to provide a voltage signal, which cooperates with the sensing electrode 151 in sensing the charge carriers from the quantum dot film 154.

In the embodiment of the present disclosure, the photosensitive device being disposed to have a vertical shift with respect to the thin film transistor means that the photosensitive device and the thin film transistor are disposed respectively and sequentially in different structure layers in the direction perpendicular to the substrate, so that the photosensitive device may be disposed at a horizontal location independent of the location of the thin film transistor and the size of the photosensitive area of the photosensitive device is independent of the location of the thin film transistor. For example, a part of the photosensitive device may be aligned with or overlap the thin film transistor in the vertical direction. Since the photosensitive device is disposed to have a vertical shift with respect to the thin film transistor, the quantum dot film of the photosensitive device may have a relatively large photosensitive area.

In some embodiments of the present disclosure, the quantum dot film functioning as the photosensitive layer has the same area as the scintillating layer, so that the visible light converted by the scintillating layer is substantially absorbed by the quantum dot film, resulting in a high signal to noise ratio and thus a relatively high detection efficiency. Theoretically, the area of the quantum dot film is approximately equal to that of a pixel region, so that a high resolution may be achieved. Therefore, compared to the structure in which the photodiode and the thin film transistor are disposed side by side, the X ray flat panel detector in the embodiment of the present disclosure may achieve both a high detection efficiency and a high resolution. At the same time, the quantum dot film with a relatively large area may be prepared with a coating process based on solution, simplifying the preparation process and reducing the production costs.

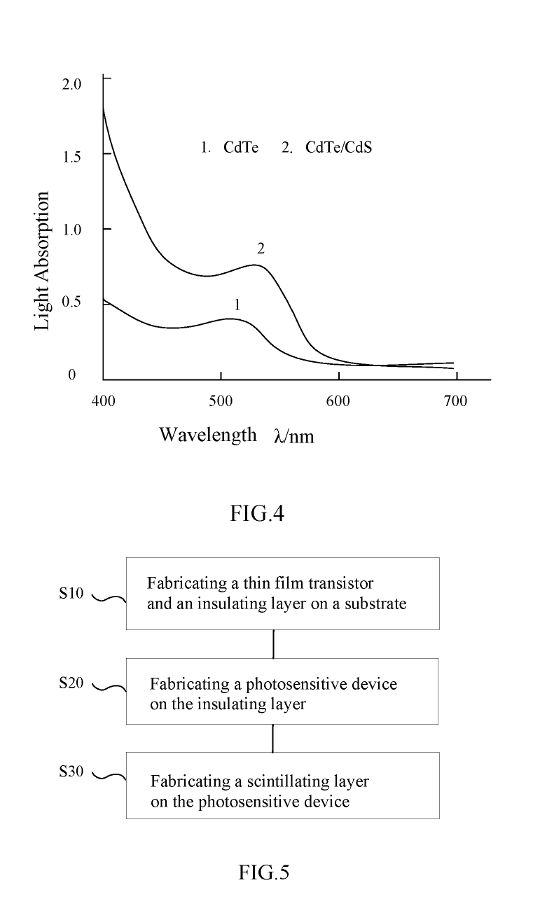

FIG. 3 is a schematic diagram illustrating the structure of pixels of an X ray flat panel detector in an embodiment of the present disclosure. As shown in FIG. 3, the X ray flat panel detector includes a plurality of gate lines 1 and a plurality of data lines 2. Each gate line and each data line perpendicularly intersect, so that a plurality of pixel regions 3 arranged in a matrix are formed on the substrate with each pixel region 3 having a thin film transistor and a photosensitive device disposed therein. The gate lines 1 are used to provide scanning signals to corresponding thin film transistors, which are turned on in response to the scanning signals from the gate lines to send sensed signals from photosensitive devices to the data lines 2. The data lines 2 then output the sensed signal to an external data processing circuit.

In some embodiments of the present disclosure, the quantum dot film may include a CdTe film, a CdTe/CdS film or the like and have a thickness of 100-300 nm. A quantum dot is also known as nano-crystal, which is a nano-particle composed of Group II-VI or III-V elements, and has a size within 100 nm in three dimensions. The electrons in a quantum dot are constrained in movement in all directions, resulting in a particularly significant quantum confinement effect, and may generate charge carriers when excited by light. FIG. 4 is a absorption spectrogram of a quantum dot film showing schematically absorption spectrums of cadmium telluride (CdTe) and cadmium telluride/cadmium sulfide (CdTe/CdS). It can be seen from FIG. 4 that light absorption in the ultraviolet and visible regions of the spectrums of CdTe and CdTe/CdS is relatively strong and has a relatively wide range. In the present embodiment, a quantum dot film is used as the photosensitive layer, so that owing to the property of the quantum dot materials that light absorption is relatively strong and has a relatively wide range in ultraviolet and visible regions of their spectrums, absorption of ultraviolet and visible light generated by the scintillating layer is enhanced, generating more charges. A relatively high photocurrent can be achieved, even though a relatively thin quantum dot film is used.

In some embodiments of the present disclosure, optionally, the substrate may use a glass substrate, a silicon wafer, a polyimide (PI) plastic substrate or the like; optionally, the driving and sensing electrodes may each use Mo, Al, any other metal or any alloy thereof or use Ag nano-wires, graphene or the like, and have a thickness of 30-200 nm; optionally, the scintillating layer is a scintillating layer composed of cesium iodide and has a thickness of 400-600 um, the cesium iodide in the scintillating layer forming a crystalline array arranged in a columnar shape; optionally, the passivation layer may use silicon nitride (SiNx), silicon oxide (SiO₂) or the like; optionally, the composite insulating layer may use a composite organic-inorganic insulating layer, i.e. being constituted by an organic insulating layer and an inorganic insulating layer. For example, the composite insulating layer may use a composite PI/SiNx film or a composite PI/SiO₂ film, and may have a thickness of 100-300 nm. By disposing a composite insulating layer between the sensing electrode and the quantum dot film, the leakage current from the quantum dot film may be reduced effectively, which enables the quantum dot film to have lower noises and a higher signal to noise ratio, resulting in a higher detection efficiency.

In some embodiments, the driving electrode and the sensing electrode may be located in a same layer, as shown in FIG. 2. In some embodiments, the driving electrode and the sensing electrode may be located in different layers. For example, the sensing electrode 151 is disposed on the insulating layer 13, while the driving electrode 152 is disposed on the composite insulating layer 153.

In some embodiments of the present disclosure, the X ray flat panel detector in the present embodiment may further include one or more metal lead wires 150 used to connect the driving electrode 152 to one or more integrated circuits. In some embodiments, the metal lead wire(s) 150 and the driving electrode 152 may be located in the same layer, as shown in FIG. 2. In some embodiments, the metal lead wire(s) 150 and the driving electrode 152 may also be located in different layers. When the metal lead wire(s) 150 and the driving electrode 152 are located in different layers, the metal lead wire(s) 150 is(are) connected to the driving electrode 152 through one or more vias.

The fabrication process of an X ray flat panel detector will be described in the following to illustrate the technical solution in accordance with an embodiment of the present disclosure.

FIG. 5 is a flow chart of a fabrication method of an X ray flat panel detector in an embodiment of the present disclosure. As shown in FIG. 5, the fabrication method of an X ray flat panel detector includes:

S10, fabricating a thin film transistor and an insulating layer on a substrate;

S20, fabricating a photosensitive device on the insulating layer; and

S30, fabricating a scintillating layer on the photosensitive device.

In some embodiments of the present disclosure, at first, the thin film transistor is fabricated on the substrate by a patterning process, the thin film transistor comprising a gate, a gate insulating layer, an active layer, a source electrode and a drain electrode; then the insulating layer and a via therein are fabricated by a patterning process, the insulating layer covering the thin film transistor and the location of the via corresponding to the drain electrode. Thereafter, the photosensitive device is fabricated by a patterning process on the substrate having the thin film transistor and the insulating layer fabricated thereon. The photosensitive device includes a sensing electrode, a driving electrode, a composite insulating layer and a quantum dot film. The sensing electrode of the photosensitive device is connected to the drain electrode of the thin film transistor through the via in the insulating layer. At last, the scintillating layer is fabricated on the substrate having the photosensitive device fabricated thereon. As used in embodiments of the present disclosure, the term “patterning process” means a process including depositing a film layer, coating photoresist, exposing with a mask, developing, etching, peeling off photoresist and the like, which, as a mature existing process, has its film materials, process operations, parameters and the like well-known.

Fabricating a thin film transistor and an insulating layer on a substrate may use a process in the related art. For example, a process including four patterning steps may be used. In the first patterning step, a gate electrode and a gate line are formed on the substrate; in the second patterning step, a gate insulating layer and an active layer are formed; in the third patterning step, source and drain electrodes as well as a data line are formed; in the fourth patterning step, an insulating layer via is formed at a position corresponding to that of the drain electrode. In the present embodiment, there is no strict distinction between the source electrode and the drain electrode; the insulating layer via may be located to correspond to the drain electrode, so that the sensing electrode may be connected to the drain electrode of the thin film transistor through the insulating layer via, or the insulating layer via may be located to correspond to the source electrode, so that the sensing electrode may be connected to the source electrode of the thin film transistor through the insulating layer via. The substrate may use a glass substrate, a silicon wafer, a PI plastic substrate or the like. The active layer includes, but not limited to, amorphous silicon, polysilicon, metal oxide or the like. The actively layer may also be constituted by an amorphous silicon layer and a doped amorphous silicon layer (also known as an ohmic contact layer). In practical implementation, the thin film transistor may also be fabricated by a process including two or three patterning steps and there is no specific limitation in this respect herein.

Fabricating a photosensitive device on the insulating layer includes:

S21, fabricating a sensing electrode and a driving electrode on the insulating layer by a patterning process, the sensing electrode being connected with the drain electrode of the thin film transistor; and

S22, fabricating a composite insulating layer and a quantum dot film.

In some embodiments of the present disclosure, fabricating a sensing electrode and a driving electrode on the insulating layer by a patterning process includes: depositing a layer of metal film on the insulating layer, coating a layer of photoresist on the metal film, exposing and developing the photoresist through a mask, removing the photoresist other than that in the areas corresponding to the locations of the sensing and driving electrodes, i.e. exposing the metal film other than that in the areas corresponding the locations of the sensing and driving electrodes, removing the exposed metal film through an etching process, and peeling off the photoresist to form the sensing and driving electrodes. In practical implementation, a metal lead wire may be fabricated simultaneously. At this point, the deposition may be performed by magnetron sputtering, evaporation, chemical vapor deposition or any other known process, the coating may use any known coating process, the etching may use any known etching process. In those aspects, no specific limitation will be set herein. In some embodiments of the present disclosure, the metal film may use Mo, Al, any other metal or any alloy thereof, and may also use Ag, nano-wires, graphene or the like. The metal film may have a thickness of 30-200 nm.

In some embodiments of the present disclosure, the composite insulating layer may include a composite organic-inorganic insulating layer. Fabricating the composite insulating layer includes: at first, depositing an organic insulating layer which may use PI and then depositing an inorganic insulating layer which may use SiNx or SiO₂ to form a composite organic-inorganic insulating layer with a thickness of 100-300 nm.

In some embodiments of the present disclosure, the quantum dot film may include a CdTe film or a CdTe/CdS film and have a thickness of 100-300 nm. The quantum dot film may be coated on the composite insulating layer by a coating process including spin coating, inkjet printing, aerosol printing, laser induced transfer printing, nano-imprinting, slit coating and the like, which are well-known by those skilled in the art and will not be described in detail herein.

Fabricating a scintillating layer on the photosensitive device includes: at first, depositing a passivation layer on the quantum dot film and then fabricating a scintillating layer on the passivation layer. In some embodiments of the present disclosure, the passivation layer may include SiNx or SiO₂. The scintillating layer may include a scintillating layer composed of cesium iodide and have a thickness of 400-600 um, the cesium iodide in the scintillating layer forming a crystalline array arranged in a columnar shape. In practical implementation, the scintillating layer may be fabricated using any suitable scintillating material which is a light wavelength conversion material converting X rays into visible light. While the passivation layer is being fabricated, a protection layer for the metal lead wire(s) may be fabricated at the same time.

An embodiment of the present disclosure further provides an X ray imaging system including the X ray flat panel detector described above. The X ray imaging system may be applied in medical examination, and a signal detected by the X ray flat panel detector may be transmitted to a control device (e.g. a computer). The control device converts the signal into an image signal and controls a display device to display the corresponding image, so that the distribution of X rays may be observed visually. Since the X ray flat panel detector in embodiments of the present disclosure has a high detection precision, images displayed in the imaging system will be more distinct and accurate.

In the X ray flat panel detector and the fabrication method thereof provided in embodiments of the present disclosure, the photosensitive device is disposed to have a vertical shift with respect to the thin film transistor, so that the photosensitive area is increased without being constrained by the thin film transistor; in addition, the photosensitive area is equal to the area of the scintillating layer and the area of the pixel region respectively, so that the detection efficiency and resolution are maximized. Furthermore, a quantum dot film is used as the photosensitive layer, so that owing to the property of the quantum dot materials that light absorption is relatively strong and has a relatively wide range in the ultraviolet and visible regions of their spectrums, absorption of ultraviolet and visible light generated by the scintillating layer is enhanced and even though a relatively thin quantum dot film is used, a relatively high quantity of charge carriers may be achieved, further improving the signal to noise ratio. When a low dose of X ray irradiation is used, the X ray flat panel detector in embodiments of the present disclosure will have such advantages as a high detection efficiency, a high resolution, a simple fabrication process and low production costs.

In embodiments of the present disclosure, the data processing circuit, the control device and the like may be implemented by various circuits with capability of logical operation, such as a central processing unit (CPU), a single chip unit (MCU), a digital signal processor (DSP), a field programmable logic array (FPGA) and the like.

In description of embodiments of the present disclosure, it is to be noted that relationships in orientation or position indicated by terms “middle”, “upper”, “lower”, “front”, “back”, “vertical”, “horizontal”, “top”, “bottom”, “inside”, “outside” etc. are those based on the indication in the accompanying drawings; they are used only for the purpose of describing embodiments of the present disclosure and simplifying the description and not intended to indicate or imply that the devices or elements involved must be in, be configured with or operate with particular orientation or position; therefore they should not be understood to function to limit the present disclosure in any way.

In the description of embodiments of the present disclosure, it is to be noted that unless otherwise stated and defined, terms “mount”, “connected with” and “connected” should be interpreted broadly. For example, it may refer to a fixed connection, a detachable connection, or an integral connection; a mechanical connection or an electrical connection; a direct connection or an indirect connection via an intermediate media, e.g. inside communication of two elements. For those skilled in the art, meanings of the above-mentioned terms in the present disclosure may be understood depending on specific circumstances.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

The implementations disclosed by the present disclosure have been described above; they are taken only in order to facilitate understanding of, rather than to limit, the present disclosure. Any modification and change in form and details may be done to the implementations by those skilled in the art without departing from the spirit and range of the present disclosure, which should be accorded the scope defined by the accompanying claims as the scope of patent protection.

1. An X ray flat panel detector comprising:
a substrate;
a thin film transistor disposed on the substrate and configured to output a sensed signal;
an insulating layer covering the thin film transistor;
a photosensitive device disposed on the insulating layer to have a vertical shift with respect to the thin film transistor, and configured to absorb visible light through a quantum dot film and convert the visible light into a sensed signal; and
a scintillating layer disposed on the photosensitive device and configured to convert X rays into the visible light.

2. The X ray flat panel detector of claim 1, wherein the photosensitive device comprises:
a sensing electrode disposed on the insulating layer, connected with a drain electrode of the thin film transistor, and configured to sense charge carriers and generate a sensed signal;
a composite insulating layer covering the sensing electrode; and
a quantum dot film disposed on the composite insulating layer and configured to absorb the visible light and convert the visible light into the charge carriers.

3. The X ray flat panel detector of claim 2, wherein the photosensitive device further comprises a driving electrode and a metal lead wire.

4. The X ray flat panel detector of claim 3, wherein the driving electrode and the metal lead wire are located in a same layer as the sensing electrode.

5. The X ray flat panel detector of claim 2, wherein the quantum dot film comprises at least one of a cadmium telluride film or a cadmium telluride/cadmium sulfide film, and has a thickness of 100-300 nm.

6. The X ray flat panel detector of claim 2, wherein the scintillating layer comprises a scintillating layer composed of cesium iodide and has a thickness of 400-600 um, the cesium iodide in the scintillating layer forming a crystalline array arranged in a columnar shape.

7. The X ray flat panel detector of claim 2, wherein the composite insulating layer comprises a composite organic-inorganic insulating layer and has a thickness of 100-300 nm.

8. The X ray flat panel detector of claim 1, further comprising a passivation layer disposed between the photosensitive device and the scintillating layer.

9. The X ray flat panel detector of claim 8, wherein the passivation layer comprises at least one of a silicon nitride layer or a silicon oxide layer.

10. An X ray imaging system comprising the X ray flat panel detector of claim 1.

11. A fabrication method of an X ray flat panel detector comprising:
fabricating a thin film transistor and an insulating layer on a substrate;
fabricating a photosensitive device on the insulating layer; and
fabricating a scintillating layer on the photosensitive device.

12. The manufacturing method of claim 11, wherein fabricating a photosensitive device on the insulating layer comprises:
fabricating a sensing electrode and a driving electrode on the insulating layer by a patterning process, the sensing electrode being connected with a drain electrode of the thin film transistor; and
fabricating a composite insulating layer and a quantum dot film.

13. (canceled)

14. (canceled)

15. (canceled)

16. The X ray imaging system of claim 10, wherein the photosensitive device comprises:
a sensing electrode disposed on the insulating layer, connected with a drain electrode of the thin film transistor, and configured to sense charge carriers and generate a sensed signal;
a composite insulating layer covering the sensing electrode; and
a quantum dot film disposed on the composite insulating layer and configured to absorb the visible light and convert the visible light into the charge carriers.

17. The X ray imaging system of claim 16, wherein the photosensitive device further comprises a driving electrode and a metal lead wire.

18. The X ray imaging system of claim 17, wherein the driving electrode and the metal lead wire are located in a same layer as the sensing electrode.

19. The X ray imaging system of claim 16, wherein the quantum dot film comprises at least one of a cadmium telluride film or a cadmium telluride/cadmium sulfide film, and has a thickness of 100-300 nm.

20. The X ray imaging system of claim 16, wherein the scintillating layer comprises a scintillating layer composed of cesium iodide and has a thickness of 400-600 um, the cesium iodide in the scintillating layer forming a crystalline array arranged in a columnar shape.

21. The X ray imaging system of claim 16, wherein the composite insulating layer comprises a composite organic-inorganic insulating layer and has a thickness of 100-300 nm.

22. The X ray imaging system of any one of claims 1-7, further comprising a passivation layer disposed between the photosensitive device and the scintillating layer.

23. The X ray imaging system of claim 22, wherein the passivation layer comprises at least one of a silicon nitride layer or a silicon oxide layer.
